(19) United States
(12) Patent Application Publication
(10) Pub. No.: US 2024/0155834 A1
(43) Pub. Date: May 9, 2024

(54) SEMICONDUCTOR STRUCTURE AND METHOD FOR FORMING SAME

(71) Applicant: CHANGXIN MEMORY TECHNOLOGIES, INC., Hefei City (CN)

(72) Inventors: YI JIANG, Hefei (CN); Qinghua HAN, Hefei (CN); Deyuan XIAO, Hefei (CN); Yunsong QIU, Hefei (CN)

(21) Appl. No.: 18/536,586

(22) Filed: Dec. 12, 2023

Related U.S. Application Data
(63) Continuation of application No. PCT/CN2022/126965, filed on Oct. 24, 2022.

(30) Foreign Application Priority Data
Aug. 15, 2022 (CN) 202210976358.2

(51) Int. Cl. H10B 12/00

(52) U.S. Cl. CPC H10B 12/482; H10B 12/02

(57) ABSTRACT

The method of forming the semiconductor structure comprises operations of: forming a substrate, and forming active regions located above the substrate and arranged at intervals in a first direction parallel to a top face of the substrate; and performing a modifying treatment to a part of the substrate below the active regions from at least one side face of the substrate, to form bit lines each of which extends in the first direction and is electrically connected with a plurality of the active regions arranged at intervals in the first direction

### CROSS-REFERENCE TO RELATED APPLICATION

This is a continuation application of International Patent Application No. PCT/CN2022/126965, filed on Oct. 24, 2022, which claims priority to Chinese patent application No. 202210976358.2, filed on Aug. 15, 2022 and entitled “SEMICONDUCTOR STRUCTURE AND METHOD FOR FORMING SAME”. The disclosures of International Patent Application No. PCT/CN2022/126965 and Chinese patent application No. 202210976358.2 are incorporated by reference herein in their entireties.

### TECHNICAL FIELD

The present disclosure relates to the field of semiconductor manufacturing technique, and in particular to a semiconductor structure and a method for forming the same.

### BACKGROUND

Dynamic Random Access Memory (DRAM) is a semiconductor device commonly used in an electronic device such as computer. DRAM consists of several memory cells, each of which usually includes a transistor and a capacitor. A gate of the transistor is electrically connected to a word line. A source of the transistor is electrically connected to a bit line. A drain of the transistor is electrically connected to the capacitor. A word line voltage of the word line can control the on-off state of the transistor, such that by means of the bit line, data information stored in the capacitor can be read, or data information can be written into the capacitor.

A buried bit line structure is usually applied in a semiconductor structures such as DRAM et al. However, during the formation of the buried bit line structure, a formation of the bit line structure is faster in a horizontal direction than in a vertical direction, resulting in a thinner thickness of the buried bit line structure. The buried bit line structure with the thinner thickness has a larger resistance, thereby reducing the electrical performance of the semiconductor structure such as DRAM et al.

Therefore, a pressing technical challenge is reducing the resistance of the buried bit line to improve the electrical performance of the semiconductor structure.

### SUMMARY

According to some embodiments, the present disclosure provides a method of forming a semiconductor structure, which includes the follow operations of:
forming a substrate, and forming active regions located above the substrate and arranged at intervals in a first direction parallel to a top face of the substrate; and
performing a modifying treatment to a part of the substrate below the active regions from at least one side face of the substrate, to form bit lines each of which extends in the first direction and is electrically connected with a plurality of the active regions arranged at intervals in the first direction.

According to other embodiments, the present disclosure further provides a semiconductor structure. The semiconductor structure includes a substrate, bit lines and active regions.

The bit lines are located on the substrate and extend in a first direction parallel to a top face of the substrate.

The active regions are located above the bit lines and arranged at intervals in a first direction. Each of the bit lines is successively electrically connected with a plurality of the active regions arranged at intervals in the first direction, a thickness of the bit lines is uniform in the first direction.

### BRIEF DESCRIPTION OF THE DRAWINGS

FIG. 1 is a flowchart of the method of forming the semiconductor structure in embodiments of the present disclosure.

FIG. 2 is a top view of the semiconductor structure formed according to embodiments of the present disclosure.

FIGS. 3 to 6 are schematic cross-sectional views of main processes during forming the semiconductor structures according to embodiments of the present disclosure.

### DETAILED DESCRIPTION

Embodiments of the semiconductor structure and the forming method thereof in the present disclosure will be described in detail below with reference to the drawings.

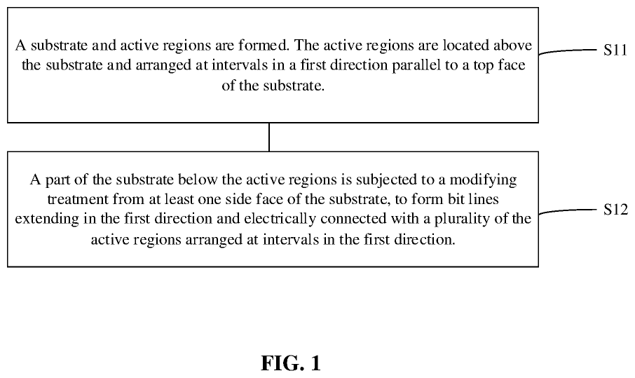

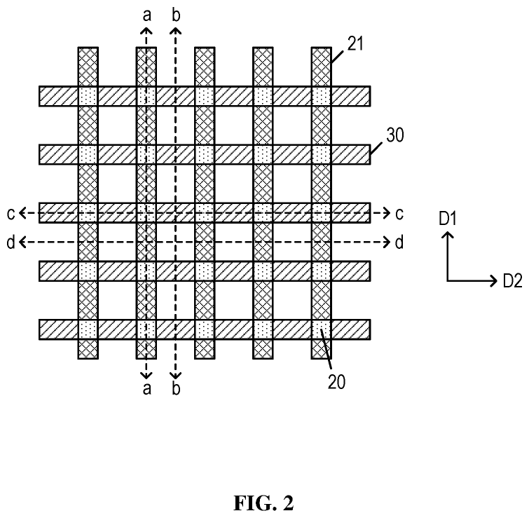

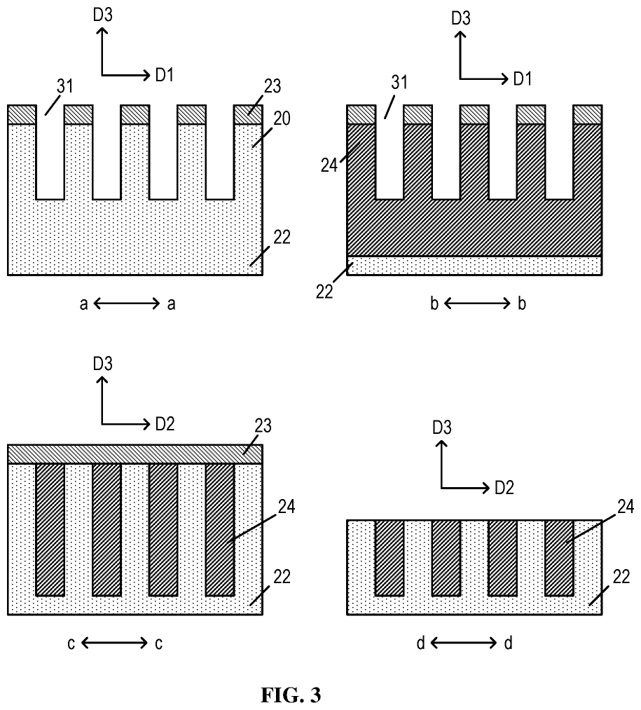

The embodiments of the present disclosure provide a method of forming a semiconductor structure. FIG. 1 is a flowchart of the method of forming the semiconductor structure in embodiments of the present disclosure. FIG. 2 is a top view of the semiconductor structure formed according to embodiments of the present disclosure. Particularly, FIGS. 3 to 6 are schematic cross-sectional views of main processes during forming the semiconductor structures according to embodiments of the present disclosure. FIGS. 3 to 6 are schematic cross-sectional views respectively at line a-a, line b-b, line c-c and line d-d in FIG. 2 during forming the semiconductor structures, so as to clearly illustrate the forming process of the semiconductor structure. As shown in FIGS. 1-6, the method of forming the semiconductor structure includes the following operations.

At S11, a substrate 22 and active regions 20 are formed. The plurality of active regions are located above the substrate 22 and arranged at intervals in a first direction D1. The first direction D1 is parallel to a top face of the substrate 22.

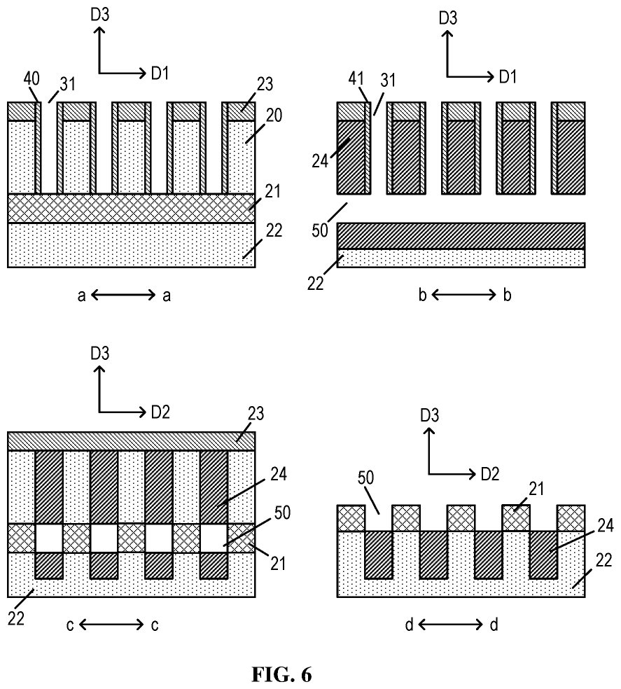

At S12, a part of the substrate 22 below the active regions 20 is subjected to a modification treatment from at least one side face of the substrate 22, so as to form bit lines 21 extending in the first direction D1 and electrically connected with a plurality of the active regions 20 arranged at intervals in the first direction D1, as shown in FIGS. 2 and 6.

In some embodiments, the forming the substrate 22 and the active regions 20 located above the substrate 22 and arranged at intervals in a first direction D1 includes the following operations.

An initial substrate is provided.

The initial substrate is etched to form a plurality of first trenches 31 arranged at intervals in the first direction D1, parts of the initial substrate remaining between the adjacent first trenches 31 form the active regions 20, and a part of the initial substrate below the first trenches 31 and the active regions 20 forms the substrate.

The semiconductor structure formed according the embodiment may be but is not limited to a DRAM. The semiconductor structure will be described below using a DRAM as an example. For example, the initial substrate may be but is not limited to a silicon substrate. In the embodiment, the initial substrate is described using a silicon substrate as an example. In other embodiments, the initial substrate may be a gallium nitride substrate, gallium arsenide substrate, gallium carbide substrate, silicon carbide substrate, or SOI substrate.

In some embodiments, the forming the plurality of first trenches 31 arranged at intervals in the first direction D1 includes the following operations.

The initial substrate is etched to form a plurality of second trenches arranged at intervals in a second direction D2. Parts of the initial substrate remaining between adjacent second trenches form a semiconductor layer, and a part of the initial substrate below the second trenches and the semiconductor layer forms the substrate 22. The second direction D2 is parallel to the top face of the substrate 22, and the first direction D1 intersects with the second direction D2.

Isolation layers 24 are formed in the second trenches.

The semiconductor layer and the isolation layers 24 are etched to form the plurality of first trenches 31 arranged at intervals in the first direction D1, and parts of the semiconductor layer remaining between the adjacent first trenches 31 form the active regions 20, as shown in FIGS. 2 and 3.

Specifically, the initial substrate can be etched in the first direction D1 by means of a photoetching process to form the second trenches, each of which extends in the first direction D1 and does not penetrate the initial substrate in the third direction. The second trenches are arranged at intervals in the second direction D2. After the second trenches are formed, parts of the initial substrate remaining between adjacent second trenches form the semiconductor layer, and a part of the initial substrate below the second trenches and the semiconductor layer forms the substrate 22. The third direction D3 is perpendicular to the top face of the substrate 22. In this embodiment, the top face of the substrate 22 refers to a surface of the substrate 22 facing the active regions 20. The wording “intersect” described in the embodiment may be vertically intersecting (i.e. orthogonally intersecting) or horizontally intersecting. An insulating dielectric material, such as an oxide material (e.g., silicon dioxide), may be deposited in second trenches through a chemical vapor deposition process, a physical vapor deposition process or an atomic layer deposition process, so as to form the isolation layer 24 fully filling the second trenches. Then, a patterned mask layer 23 is formed above the initial substrate, for example, above the semiconductor layer and the isolation layers 24. The mask layer 23 includes etching windows from which parts of the semiconductor layer and parts of the isolation layer 24 are exposed. Thereafter, the semiconductor layer and the isolation layer 24 are etched downward through the etching windows in the mask layer 23, to form the first trenches 31 arranged at intervals in the first direction D1. Each first trench 31 extends in the second direction D2. Parts of the semiconductor layer remaining between the adjacent first trenches 31 form the active regions 20, as shown in FIGS. 2 and 3. In the third direction D3, a depth of each first trench 31 is less than a depth of each isolation layer 24, i.e. a top face of each first trench 31 is located above a top face of the isolation layer 24. A depth difference between each first trench 31 and each isolation layer 24 in the third direction D3 can be determined according to actual requirements, such as a thickness of the bit line 21 to be formed subsequently. In an example, a material of the mask layer 23 is a nitride material (e.g. silicon nitride).

In some embodiments, before the part of the substrate 22 below the active regions 20 is subjected to the modification treatment from at least one side face of the substrate 22, the method further includes following operations.

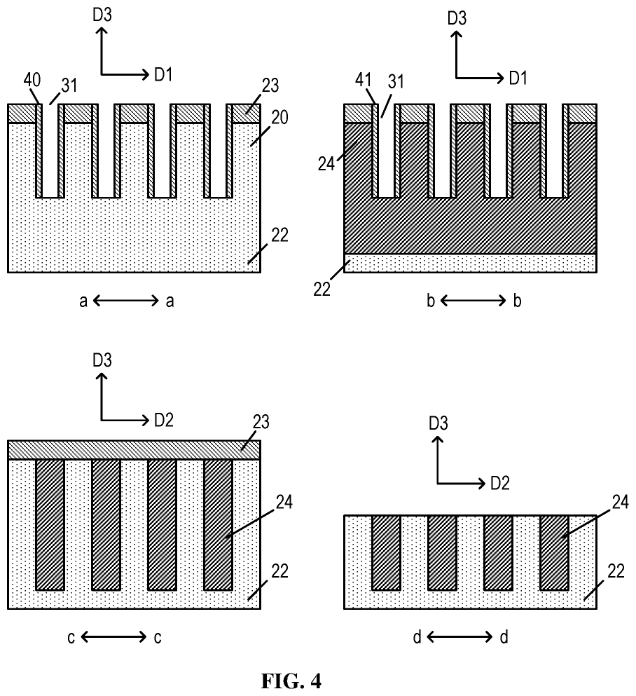

A first protection layer 40 covering side walls of parts of the first trenches 31 in the semiconductor layer is formed, as shown in FIGS. 4.

Specifically, a nitride material (such as silicon nitride) may be deposited on the entire inner walls (including the side walls and bottom walls) of parts of the first trenches 31 in the semiconductor layer, to form the first protection layer 40. Then, a part of the first protection layer 40 located on the bottom wall of each of the first trenches 31 in the semiconductor layer is etched back to expose a part of the substrate 22 below the first trenches 31. The first protection layer 40 covering the side walls of the first trenches 31 are used to protect side walls of the active regions 20, to avoid damage to the active regions 20 caused by the subsequent process of forming the bit line 21, thereby further ensuring the electrical performance of the semiconductor structure. A material of the first protection layer 40 in this embodiment will be described using a nitride material (e.g. silicon nitride) as an example. In other embodiments, the material of the first protection layer 40 may also be other insulating dielectric material, as long as that a high etch selectivity ratio of the first protection layer 40 to the substrate 22 is ensured. In an example, the etch selectivity ratio of the first protection layer 40 to the substrate 22 is greater than 3.

In some embodiments, the modification of the part of the substrate 22 below the active regions 20 from at least one side face of the substrate 22 includes the following operations.

The part of the substrate 22 below the active regions 20 is subjected to the modification treatment in the second direction D2.

Specifically, according to a pre-determined layout design, the pre-formed bit line 21s extend in the first direction D1. The modification of the part of the substrate 22 below the active regions 20 in the second direction D2 can improve a forming efficiency of the bit line 21 and can improve a thickness uniformity of the bit line 21 in the second direction D2.

In order to further improve the forming efficiency of the bit line 21, in some embodiments, the modification of the part of the substrate 22 below the active regions 20 in the second direction D2 includes the following operation.

The part of the substrate 22 below the active regions 20 is subjected to modification treatments simultaneously from two side faces of the substrate 22 opposite to one another in the second direction D2.

In some embodiments, a depth of each second trench is greater than the depth of each first trench 31 in the third direction D3. The third direction D3 is perpendicular to the top face of the substrate 22. The modification of the part of the substrate 22 below the active regions 20 from at least one side face of the substrate 22 includes the following operations.

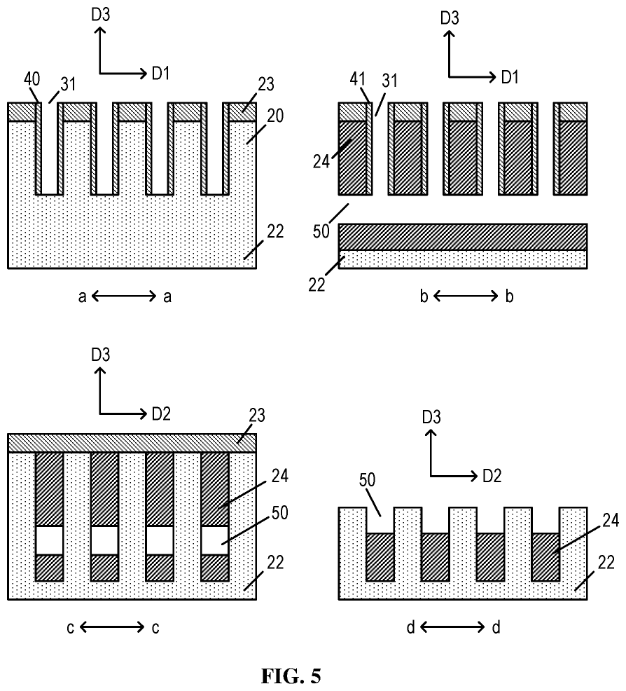

Parts of the isolation layers 24 below the first trenches 31 are etched along the first trenches 31, to form, in the isolation layers 24, etched grooves 50 located below the first trenches 31, as shown in FIG. 5.

The part of the substrate 22 below the active regions 20 is subjected to the modification treatment along the etched grooves 50.

In some embodiments, before the parts of the isolation layers 24 below the first trenches 31 are etched along the first trenches 31, the method further includes the following operations.

A second protection layer 41 covering the side walls of parts of the first trenches 31 in the isolation layers 24 are formed, as shown in FIG. 5.

Specifically, in order to further simplify the forming process of the semiconductor structure, the second protection layer 41 covering the side walls of parts of the first trenches 31 in the isolation layers 24 can be formed simultaneously with the first protection layer 40 covering the side walls of parts of the first trenches 31 in the semiconductor layer. For example, the nitride material (such as silicon nitride) may be deposited on the entire inner walls (including the side walls and bottom walls) of the first trenches 31. Then, the nitride material located on the bottom walls of the first trenches 31 is etched back. The nitride material remaining on the side walls of parts of the first trenches 31 in the semiconductor layer forms the first protection layer 40. The nitride material remaining on the side walls of parts of the first trenches 31 in the isolation layers 24 forms the second protection layer 41. The second protection layer 41 protect the side walls of the first trenches 31, so as to avoid a damage to the side walls of the first trenches 31 during the subsequent processes of forming the etched grooves 50.

In some embodiments, the forming, in the isolation layers 24, the etched grooves 50 located below the first trenches 31 includes the following operations.

The parts of the isolation layers 24 below the first trenches 31 are anisotropically etched along the first trenches 31 in such a way that an etching rate for the isolation layer 24 in the first direction D1 is greater than an etching rate in the third direction D3. In this way, the etched grooves 50, which extend in the first direction D1 and successively communicate with the plurality of first trenches 31 arranged at intervals in the first direction D1, are formed in the isolation layers 24.

Specifically, an appropriate etching agent can be selected or etching parameters (e.g. etching temperature, etching pressure, plasma concentration, etc.) can be adjusted, so as to allow that the etching rate for the isolation layers 24 in the first direction D1 is greater than the etching rate in the third direction D3. That is, the isolation layers are etched faster in the first direction than in the third direction. Therefore, the etched grooves 50 are able to successively communicate with the plurality of the first trenches 31 arranged at intervals in the first direction D1, and the etched grooves do not penetrate the isolation layers 24 in the third direction D3, so as to avoid damage to the substrate 22 below the isolation layers 24. Those skilled in the art can control a depth of the etched grooves 50 in the third direction according to actual requirements, for example by controlling etching parameters, such as etching time, etching agent dosage, et al., such that a thickness in the third direction D3 of the bit line 21 formed subsequently can be flexibly adjusted.

In other embodiments, the forming, in isolation layers 24, the etched grooves 50 located below the first trenches 31 includes the following operations.

The parts of isolation layers 24 below the first trenches 31 are etched along the first trenches 31 through a selective etching process. In this way, the etched grooves 50, which extend in the first direction D1 and successively communicate with the plurality of first trenches 31 arranged at intervals in the first direction D1, are formed in each isolation layer 24.

Specifically, the selective etching process is applied to etch the parts of the isolation layers 24 below the first trenches 31 along the first trenches 31, so that an etching degree of the parts of the isolation layers 24 below the first trenches 31 along the first direction D1 is greater than an etching degree of the parts of the isolation layers 24 along the third direction D3. In this way, the etched grooves 50 are able to successively communicate with the plurality of the first trenches 31 arranged at intervals in the first direction D1, and do not penetrate the isolation layers 24 in the third direction D3, so as to avoid the damage to the substrate 22 below the isolation layers 24.

In some embodiments, the forming, in isolation layers 24, the etched grooves 50 located below the first trenches 31 includes the following operations.

The parts of the isolation layer 24 below the first trenches 31 are etched along the first trenches 31 through a wet etching process. The etched grooves 50, which extend in the first direction D1 and successively communicate with the plurality of first trenches 31 arranged at intervals in the first direction D1, are formed in the isolation layers 24.

Specifically, after the second protection layer 41 covering the side walls of parts of the first trenches 31 in the isolation layers 24 are formed, the parts of the isolation layers 24 below the first trenches 31 can be etched along the first trenches 31 through a wet etching process, to simplify the forming process of the etched groove 50. By adjusting etching parameters of the wet etching process, such as the type of etch agent, etching temperature, etc., the formed etched grooves 50 are able to successively communicate with the first trenches 31 arranged at intervals in the first direction D1, and the etched grooves do not penetrate the isolation layers 24 in the third direction D3, so as to avoid the damage to substrate 22 below the isolation layers 24.

In an example, a length of each etched groove 50 in the first direction D1 is greater than or equal to a length of the semiconductor layer in the first direction D1, thereby ensuring that the bit lines 21 formed through the etched grooves 50 are able to be electrically connected with the active regions 20 arranged at intervals in the first direction D1. A width of each etched groove 50 in the second direction D2 may be less than or equal to a width of each isolation layer 24 in the second direction D2, so as to enlarge process windows for the modification and avoid damages to the active regions 20.

The modification is to modify a part of the substrate 22 below the active regions 20 to allow the modified part of the substrate 22 has an improved conductivity, so as to form the bit lines 21 electrically connected with a plurality of the active regions 20 arranged at intervals in the first direction D1. In some embodiments, the modification is a treatment forming metal silicide or an ion implantation doping treatment.

In some embodiments, the modification of the part of the substrate 22 below the active regions 20 along the etched grooves 50 includes the following operations.

A metal material is deposited, on the side faces of the part of the substrate 22 below the active regions 20, along the etched grooves 50.

A annealing treatment is performed to the part of the substrate 22 to form the bit lines 21.

In some embodiments, the metal material is one or more of Ti, Co, Mo, Ni, and Sn. For example, if the metal material is Ti, the chemical vapor deposition process can be used for deposition; if the metal material is Co, the atomic layer deposition process can be used for deposition.

In some embodiments, the annealing treatment of the part of the substrate 22 below the active regions 20 includes the following operations.

The part of the substrate 22 is subjected to a first annealing treatment at a first temperature, to form initial bit lines.

A part of the metal material which does not participate in a reaction is removed.

The initial bit lines are subjected to a second annealing treatment at a second temperature higher than the first temperature, to form the bit lines 21.

The modification in the following processes is described using a treatment forming metal silicide as an example, and the annealing treatment is described using Rapid Thermal Processing (RTP) as an example. For example, each etched groove 50 exposes two side walls opposite to one another in the second direction D2 of the substrate 22 below the active regions 20. After the etched grooves 50 are formed, metal Ti may be deposited along the etched grooves 50 on two opposite side walls in the second direction D2 of part of the substrate 22 below the active regions 20 through the chemical vapor deposition process. Alternately, metal Co is deposited along the etched grooves 50 on two opposite side walls in the second direction D2 of the part of the substrate 22 below the active regions 20 through the atomic layer deposition process. Thereafter, the substrate 22 is subjected to the first annealing treatment at a lower temperature, i.e. the first temperature, such that a part of the metal material reacts with the silicon material in the substrate 22 to form a high-resistance metal silicide material which forms the initial bit lines. Next, the part of the metal material which does not participate in the reaction is removed by etching, and the initial bit lines are subjected to the second annealing treatment at a higher temperature, i.e. the second temperature, to form the bit lines 21 with low resistance. In an example, the first temperature is comprised between 500° C. and 700° C., and the second temperature is comprised between 850° C. and 1000° C.

This embodiment is described using two annealing treatment respectively at a low temperature and a high temperature as an example. In other embodiments, only one annealing treatment may be performed to simplify the forming process of the semiconductor structure.

In some embodiments, after the bit lines are formed, the method further includes the following operations.

Dielectric layers which fully fill parts of the first trenches 31 in the isolation layers 24 are formed. The etched grooves 50 remaining below the dielectric layer form air gaps between the adjacent bit lines 21.

Specifically, the dielectric layers fill only parts of the first trenches 31 in the isolation layers 24, and the etched grooves form the air gaps between the adjacent bit lines 21, such that an electrical isolation effect between the adjacent bit lines 21 can be further enhanced due to a low dielectric constant of air. In an embodiment, a material of the dielectric layers may be an oxide material (e.g. silicon dioxide).

In order to further simplify the forming process of the semiconductor structure, in some embodiments, after the bit lines are formed, the method further includes the following operations.

Dielectric layers, which fully fill parts of the first trenches 31 in the isolation layers 24 and the etched grooves 50, are formed.

In an embodiment, after the bit lines 21 are formed, a channel region, a source region and a drain region can be defined in each active region 20. The source region and the drain region are distributed on two opposite sides of the channel region in the third direction D3 respectively. The source region is electrically connected to respective one of the bit lines 21. Then, a conductive material such as TiN or metallic tungsten is deposited along the first trenches 31 to form the word lines 30 covering the channel regions. As shown in FIG. 2, the word lines 30 extend in the second direction D2 and successively cover the channel regions in a plurality of the active regions 20 arranged at intervals in the second direction D2. The word lines 30 are arranged at intervals in the first direction D1. Next, above each drain region, a capacitor electrically connected with the respective one of the drain regions may be formed.

The embodiments of the present disclosure further provide a semiconductor structure, which can be formed through the method of forming the semiconductor structure as shown in FIGS. 1-6. Schematic views of the semiconductor structure in the embodiments of the present disclosure are shown in FIGS. 2 and 6. As shown in FIGS. 1-6, the semiconductor structure includes the substrate 22, the bit lines 21, and the active regions 20.

The bit lines 21 are located on the substrate 22 and extend in the first direction D1. The first direction D1 is parallel to the top face of the substrate 22;

[symbol]

The active regions 20 are located above the bit lines 21 and arranged at intervals in the first direction D1. The bit lines 21 are successively electrically connected with a plurality of the active regions 20 arranged at intervals in the first direction D1. A thickness of the bit lines 21 is uniform in the first direction D1.

The semiconductor structure formed in this embodiment may be but is not limited to a DRAM. The semiconductor structure will be described using the DRAM as an example. For example, the substrate 22 may be but is not limited to a silicon substrate. The embodiment is described using a silicon substrate as an example. In other embodiments, the substrate 22 may be a semiconductor substrate, such as gallium nitride substrate, gallium arsenide substrate, gallium carbide substrate, silicon carbide substrate, or Silicon-On-Insulator (SOI) substrate. The top face of the substrate 22 refers to a surface of the substrate 22 facing the active regions 20.

In this embodiment, the thickness of the bit lines 21 refers to a thickness of the bit lines 21 in the third direction D3. The third direction D3 is perpendicular to the top face of the substrate 22. In this embodiment, due to the uniform thickness distribution of the bit lines 21 in the extending direction thereof, the electric signal can be stably transmitted along the bit lines 21, thereby ensuring an uniformity of the electric signal obtained by the active regions electrically connected with the bit lines 21. In addition, it is also possible to reduce the resistance of the bit lines 21, thereby improving the electrical property of the semiconductor structure.

In some embodiments, the bit lines 21 are arranged at intervals in the second direction D2. The second direction D2 is parallel to the top face of the substrate 22, and the first direction D1 intersects with the second direction D2. The semiconductor structure further includes isolation layers 24.

Each isolation layer 24 is located between the bit lines 21 arranged at intervals in the second direction D2. Bottom faces of isolation layers 24 are located below bottom faces of the bit lines 21 in a third direction D3. The third direction D3 is perpendicular to the top face of the substrate 22.

Specifically, the active regions 20 are arranged, in a two-dimensional array in the first direction D1 and the second direction D2, above the substrate 22, to form an active array structure. The isolation layers 24 extend in the first direction D1, and t are arranged at intervals in the second direction D2. Each isolation layer 24 is located between the adjacent bit lines 21 arranged at intervals in the second direction D2 and between two adjacent rows of the active regions 20 arranged at intervals in the second direction D2, so as to electrically isolate the adjacent bit lines 21 in the second direction D2 and to electrically isolate the adjacent active regions 20 in the second direction D2. The isolation layers 24 have a greater depth in the third direction D3 to form the bit lines 21 with a greater and uniform thickness, that is, the part of the substrate 22 below the active regions 20 is modified from a side face of the substrate 22, so as to form the bit lines 21 with a uniform thickness. In an example, a material of the isolation layers 24 is an oxide material (e.g. silicon dioxide).

In some embodiments, the semiconductor structure further includes air gaps.

The air gaps are located in the isolation layers 24 and extend in the first direction D1. The air gaps are aligned with the bit lines 21.

In some embodiments, in the third direction D3, a top face of each air gap is flush with a top face of each bit line 21, and a bottom face of each air gap is flush with a bottom face of each bit line 21.

In the first direction D1, a length of the air gaps is equal to a length of the bit lines 21.

Specifically, the air gaps and the bit lines 21 are arranged alternately in the second direction D2. On the one hand, the presence of the air gaps can further enhanced the electrical isolation effect between the adjacent bit lines 21 due to a low dielectric constant of air; on the other hand, at the positions where the air gaps are located, the silicon material below the active regions 20 is modified from the side faces, so as to form the bit lines 21.

In some embodiments, the semiconductor structure further includes dielectric layers.

The dielectric layers are located in the isolation layers 24 and extend in the first direction D1. The dielectric layers are aligned with the bit lines 21.

In some embodiments, in the third direction D3, a top face of each dielectric layer is flush with the top face of each bit line 21, and a bottom face of each dielectric layer is flush with the bottom face of each bit line 21.

In the first direction D1, a length of the dielectric layers is equal to the length of the bit lines 21.

In some embodiments, a material of the bit lines 21 is a metal silicide material or a silicon material including doping ions. In an example, the material of the bit lines 21 is titanium silicon compound or cobalt silicon compound.

In order to further reduce the resistance of the bit lines 21, in some embodiments, a thickness of the bit lines 21 is comprised between 5 nm and 50 nm.

In the semiconductor structure and the method thereof in some embodiments of the present disclosure, the bit lines are formed through the modification of a part of the substrate below the active regions form a side of the substrate, such that the formed bite lines have an uniform and greater thickness, thereby effectively reducing the resistance of the bit lines and rendering the thickness distribution of each bit line uniform in the extending direction thereof. In this way, the electrical performance of the semiconductor structure is also improved. In other embodiments of the present disclosure, the part of the substrate below the active regions 20 is modified simultaneously from two side faces of the substrate opposite to each other in the second direction, so as to further improve the forming efficiency of the bit lines, and further improve the uniformity of the thickness distribution of the bit lines, thereby further improving the electrical performance of the semiconductor structure.

The embodiments described above are only preferred embodiments of the present disclosure. It should be noted that several improvements and modifications may be made by those skilled skill in the art without departing from the principles of the present disclosure, and these improvements and modifications should also be considered as within the protection scope of the present disclosure.

1. A method of forming a semiconductor structure, comprising:
forming a substrate, and forming active regions located above the substrate and arranged at intervals in a first direction parallel to a top face of the substrate; and
performing a modifying treatment to a part of the substrate below the active regions from at least one side face of the substrate, to form bit lines each of which extends in the first direction and is electrically connected with a plurality of the active regions arranged at intervals in the first direction.

2. The method of forming the semiconductor structure according to claim 1, wherein the forming the substrate and forming the active regions located above the substrate and arranged at intervals in the first direction comprises:
providing an initial substrate; and
etching the initial substrate to form first trenches arranged at intervals in the first direction, wherein parts of the initial substrate remaining between adjacent first trenches forms the active regions, and a part of the initial substrate remaining below the first trenches and the active regions forms the substrate.

3. The method of forming the semiconductor structure according to claim 2, wherein the forming the first trenches arranged at intervals in the first direction comprises:
etching the initial substrate to form second trenches arranged at intervals in a second direction parallel to the top face of the substrate, wherein a part of the initial substrate remaining between adjacent second trenches forms a semiconductor layer, a part of the initial substrate remaining below the second trenches and the semiconductor layer forms the substrate, wherein the second direction, the first direction intersects with the second direction;
forming isolation layers in the second trenches; and
etching the semiconductor layer and the isolation layers to form the first trenches arranged at intervals in the first direction, wherein parts of the semiconductor layer remaining between adjacent first trenches form the active regions.

4. The method of forming the semiconductor structure according to claim 3, wherein before the performing the modifying treatment to the part of the substrate below the active regions from at least one side face of the substrate, the method further comprises:
forming a first protection layer covering side walls of parts of the first trenches in the semiconductor layer.

5. The method of forming the semiconductor structure according to claim 3, wherein the performing the modifying treatment to the part of the substrate below the active regions from at least one side face of the substrate comprises:
performing the modifying treatment to the part of the substrate below the active regions in the second direction.

6. The method of forming the semiconductor structure according to claim 5, wherein the performing the modifying treatment to the part of the substrate below the active regions in the second direction comprises:
performing the modifying treatment to the part of the substrate below the active regions simultaneously from two side faces of the substrate opposite to each other in the second direction.

7. The method of forming the semiconductor structure according to claim 5, wherein a depth of the second trenches is greater than a depth of the first trenches in a third direction, the third direction is perpendicular to the top face of the substrate,
wherein the performing the modifying treatment to the part of the substrate below the active regions from at least one side face of the substrate comprises:
etching parts of the isolation layers below the first trenches along the first trenches, to form, in the isolation layers, etched grooves located below the first trenches; and
performing the modifying treatment to the part of the substrate below the active regions along the etched grooves.

8. The method of forming the semiconductor structure according to claim 7, wherein before the etching the parts of the isolation layers below the first trenches along the first trenches, the method further comprises:
forming a second protection layer covering side walls of parts of the first trenches in the isolation layers.

9. The method of forming the semiconductor structure according to claim 7, wherein the etching parts of the isolation layers below the first trenches along the first trenches, to form in the isolation layers, etched grooves located below the first trenches comprises:
anisotropically etching the parts of the isolation layers below the first trenches along the first trenches in such a way that an etching rate for the isolation layers in the first direction is greater than an etching rate in the third direction, to form, in the isolation layers, the etched grooves extending in the first direction and successively connected with the plurality of the first trenches arranged at intervals in the first direction.

10. The method of forming the semiconductor structure according to claim 7, wherein the etching parts of the isolation layers below the first trenches along the first trenches, to form, in the isolation layers, etched grooves located below the first trenches comprises:
etching the parts the isolation layers below the first trenches along the first trenches through a selective etching process, to form, in the isolation layers, the etched grooves extending in the first direction and successively connected with the plurality of the first trenches arranged at intervals in the first direction.

11. The method of forming the semiconductor structure according to claim 7, wherein the etching parts of the isolation layers below the first trenches along the first trenches, to form in the isolation layers, etched grooves located below the first trenches comprises:
etching the parts of the isolation layers below the first trenches along the first trenches through a wet etching process, to form, in the isolation layers, the etched grooves extending in the first direction and successively connected with the plurality of the first trenches arranged at intervals in the first direction.

12. The method of forming the semiconductor structure according to claim 7, wherein the modifying treatment is a treatment for forming metal silicide or an ion implantation doping treatment.

13. The method of forming the semiconductor structure according to claim 12, wherein the performing the modifying treatment to the part of the substrate below the active regions along the etched grooves comprises:
depositing a metal material on side faces of the part of the substrate below the active regions along the etched grooves; and
performing an annealing treatment to the part of the substrate to form the bit lines.

14. The method of forming the semiconductor structure according to claim 13, wherein the metal material is one or more of Ti, Co, Mo, Ni or Sn.

15. The method of forming the semiconductor structure according to claim 14, wherein the performing the annealing treatment to the part of the substrate below the active regions comprises:
performing a first annealing treatment to the part of the substrate at a first temperature, to form initial bit lines;
removing a part of the metal material which does not participate in a reaction of the first annealing treatment; and
performing a second annealing treatment to the initial bit lines at a second temperature higher than the first temperature, to form the bit lines.

16. The method of forming the semiconductor structure according to claim 13, wherein after the formation of the bit lines, the method further comprises:
forming dielectric layers, which fully fill parts of the first trenches in the isolation layers, wherein the etched grooves remaining below the dielectric layers form air gaps between the adjacent bit lines.

17. The method of forming the semiconductor structure according to claim 13, wherein after the formation of the bit lines, the method further comprises:
forming dielectric layers, which fully fill the etched groove and parts of the first trenches in the isolation layers.

18. A semiconductor structure, comprising:
a substrate;
bit lines located on the substrate and extending in a first direction parallel to a top face of the substrate; and
active regions located above the bit lines and arranged at intervals in a first direction, each of the bit lines being successively electrically connected with a plurality of the active regions arranged at intervals in the first direction, a thickness of the bit lines being uniform in the first direction.

19. The semiconductor structure according to claim 18, wherein the bit lines are arranged at intervals in a second direction parallel to the top face of the substrate, the first direction intersecting with the second direction; the semiconductor structure further comprises:
isolation layers, each of which is located between the bit lines arranged at intervals in the second direction, bottom faces of the isolation layers being located below bottom faces of the bit lines in a third direction perpendicular to the top face of the substrate,
air gaps located in the isolation layers and extending in the first direction, the air gaps being aligned with the bit lines, and
dielectric layers located in the isolation layers and extending in the first direction, the dielectric layers being aligned with the bit lines.

20. The semiconductor structure according to claim 19, wherein in the third direction, a top face of each of the air gaps is flush with a top face of each of the bit lines, and a bottom face of each of the air gaps is flush with a bottom face of each of the bit lines;
in the first direction, a length of the air gaps is equal to a length of the bit lines;
wherein in the third direction, a top face of each of the dielectric layers is flush with the top face of each of the bit lines, and a bottom face of each of the dielectric layers is flush with the bottom face of each of the bit lines;
in the first direction, a length of the dielectric layers is equal to the length of the bit lines,
wherein a material of the bit lines is a metal silicide material or a silicon material comprising doping ions, and
wherein a thickness of the bit lines is comprised between 5 nm and 50 nm.
